(19) United States
(12) Patent Application Publication
(10) Pub. No.: US 2017/0047455 A1
(43) Pub. Date: Feb. 16, 2017

(54) SENSING CHIP PACKAGE AND A MANUFACTURING METHOD THEREOF

(71) Applicant: XINTEC INC., Taoyuan City (TW)

(72) Inventors: Ho-Yin YIU, Hsinchu City (TW); Ying-Nan WEN, Hsinchu City (TW); Tsang-Yu LIU, Zhubei City (TW)

(21) Appl. No.: 15/231,590

(22) Filed: Aug. 8, 2016

Related U.S. Application Data
(60) Provisional application No. 62/204,175, filed on Aug. 12, 2015.

(51) Int. Cl. H01L 31/0216; H01L 31/18; H01L 33/00; H01L 33/46; H01L 33/52

(52) U.S. Cl. CPC H01L 31/02164; H01L 33/46; H01L 33/52; H01L 33/005; H01L 31/18

(57) ABSTRACT

This present invention provides a novel sensing chip package and a manufacturing method thereof, and in particular provides a proximity sensing chip package and a manufacturing thereof, which is characterized by forming a light blocking layer surrounding the light emitting device of the sensor to block the lateral light emitted by the light emitting device to reduce the interference of the lateral light and enhance the sensitivity of the light sensing device.

This application claims the benefit of U.S. provisional application No. 62/204,175, filed on Aug. 12, 2015, and the entirety of which is incorporated by reference herein.

### BACKGROUND OF THE INVENTION

Field of the Invention

The present invention relates to a sensing chip package and in particular relates to a proximity sensing chip package and a manufacturing method thereof.

Description of the Related Art

With the developments of technology, portable devices like PDA, smart phone or MP4 become more and more popular. Most of the portable devices are equipped with touch screens with proximity sensors to detect objects or obstacles in the front by an optical sensing way. The proximity sensor can be applied in smart phone or handset phone to judge if the user is close to telephone transmitter or the microphone, or be applied in a house-keeping robot to judge if there is any furniture or people in front of it.

FIG. 1A is a top view of a conventional proximity sensing chip package, and FIG. 1B is a cross-sectional view of a conventional proximity sensing chip package. As illustrated in FIG. 1A, the proximity sensing chip package 1000 comprises a proximity sensor 100 having a first top surface 100a and a first bottom surface 100b opposite to each other, wherein a light emitting device 120 and a light sensing device 110 are formed the first top surface. Besides, as illustrated in FIG. 1B, the first top surface 100a of the proximity sensor 100 is capped by a cap layer 130 having a first cavity 140 corresponding to the light emitting device 120 and a second cavity 150 corresponding to the light sensing device 110. Owing to the demand of size shrinkage of the device, a point light source such as LED and in particular an IR LED is usually used as the light emitting device 120. However, the emitting path of the point light source is non-directional, so the light angle of the point light source is usually greater than 180 degrees. In additional, the cap layer 130 is usually consisted of a material with a hardness greater than 8, such as glass, sapphire or silicon nitride, and these materials can't block the transmission of visible light. Therefore, the light sensing device 110 adjacent to the light emitting device 120 will be interfered by the lateral light emitted by the light emitting device 120 as the dashed arrows shown in the FIGS. 1A˜1B. Consequently, the sensitivity of the proximity sensing chip package 1000 is reduced.

In order to resolve above-mentioned problems, this invention provides a novel sensing chip package and a manufacturing method thereof, and in particular provides a proximity sensing chip package and a manufacturing thereof, which is characterized by forming a light blocking layer surrounding the light emitting device of the sensor to block the lateral light emitted by the light emitting device to reduce the interference of the lateral light and enhance the sensitivity of the light sensing device.

### SUMMARY OF THE INVENTION

A feature of this invention provides a sensing chip package, comprising: a sensor, having a first top surface and a first bottom surface opposite to each other, comprising a light emitting device and a light sensing device are depicted adjacent to the first top surface and spaced with a pre-determined distance, and a first conductive pad adjacent to the light emitting device and a second conductive pad adjacent to the light sensing device, whereby the light sensing device having a second top surface and a second bottom opposite to each other; and a light blocking layer formed on the first top surface of the sensor and surrounded the light emitting device, comprising a cap layer having a third top surface and a third bottom surface opposite to each other formed on the first top surface of the sensor, and the cap layer having a trench with an inner wall and a bottom wall not higher than the second bottom surface of the light sensing device; a adhesive layer sandwiched between the cap layer and the first top surface of the sensor to bound the cap layer to the first top surface of the sensor; and a light blocking material layer overlaid the inner wall of the trench or gap-filled in the trench.

Another of this invention provides a sensing chip package as mentioned above, wherein the sensor is a proximity sensor.

Another of this invention provides a sensing chip package as mentioned above, wherein the light blocking material layer is a black resistant which can absorb light.

Another of this invention provides a sensing chip package as mentioned above, wherein the light blocking material layer is a metal with a high reflection coefficient or a distributed Bragg reflector.

Another of this invention provides a sensing chip package as mentioned above, wherein the light emitting device is a LED.

Another of this invention provides a sensing chip package as mentioned above, wherein the LED is a surface mounted LED selected from mesa-type LED, vertical-type LED and flip-chip LED mounted on the first top surface of the sensor by surface mounting technology.

Another of this invention provides a sensing chip package as mentioned above, wherein the LED is a non-surface mounted LED buried in the wafer and adjacent to the first top surface.

Another of this invention provides a sensing chip package as mentioned above, wherein the LED is an IR LED.

Another of this invention provides a sensing chip package as mentioned above, wherein the light sensing device is an IR sensor.

Another of this invention provides a sensing chip package as mentioned above, further comprising a first solder wire connecting to the first conductive pad and a second solder wire connecting to the second conductive pad.

Another of this invention provides a sensing chip package as mentioned above, further comprising: an insulating layer formed on the first bottom surface of the sensor, having a first through hole exposing the first conductive pad and a second through hole exposing the second conductive pad; a re-distribution layer formed on the insulating layer and interconnected the first conductive pad and the second conductive pad via the first through hole and the second through hole respectively; a passivation layer overlaid the re-distribution layer, the first through hole, the second through hole, wherein the passivation layer has a first opening and a second opening exposing the re-distribution layer; and a first conductive structure formed in the first opening and a second conductive structure formed in the second opening and respectively interconnected to the re-distribution layer.

Another of this invention provides a sensing chip package as mentioned above, wherein the first structure and the second structure comprise solder ball, solder bumps and conductive pillars.

Another of this invention provides a sensing chip package as mentioned above, further comprising: an insulating layer formed on the first bottom surface of the sensor, having a first notch exposing an edge of the first conductive pad and a second notch exposing an edge of the second conductive pad, and part of the third bottom surface of the cap layer; a re-distribution layer formed on the insulating layer, the first notch and the second notch to interconnect the exposed edges of the first and the second conductive pads respectively; a passivation layer overlaid the re-distribution layer, the first notch and the second notch, wherein the passivation layer has a third opening and a fourth opening exposing the re-distribution layer; and a third conductive structure formed in the third opening and a fourth conductive structure formed in the fourth opening and respectively interconnected to the re-distribution layer.

Another of this invention provides a sensing chip package as mentioned above, wherein the third structure and the fourth structure comprise solder ball, solder bumps and conductive pillars.

Another feature of this invention provides a method of manufacturing a sensing chip package, comprising the steps of: providing a wafer having a plurality of sensing areas, each sensing area comprising a sensor having a first top surface and a first bottom surface opposite to each other comprising a light emitting device and a light sensing device are depicted adjacent to the first top surface and spaced with a pre-determined distance, and a first conductive pad adjacent to the light emitting device and a second conductive pad adjacent to the light sensing device, whereby the light sensing device having a second top surface and a second bottom opposite to each other; providing a cap layer having a third top surface and a third bottom surface opposite to each other, and the third bottom surface corresponding to each of the sensing areas including a first cavity corresponding to the light emitting device and a second cavity corresponding to the light sensing device; bonding the third bottom surface of the cap layer to the first top surface of the wafer by sandwiched an adhesive layer therebetween; forming a trench passing through the cap layer, the adhesive layer and part of the first top surface of the wafer and surrounding the light emitting device, wherein the trench has an inner wall and a bottom wall not higher than the light sensing device; formed on the first top surface of the sensor, and the cap layer having a trench with an inner wall and a bottom wall not higher than the second bottom surface of the light sensing device; forming a light blocking material layer to overlay the inner wall of the trench or gap-fill into the trench; removing the third top surface of the cap layer and the light blocking layer above the first cavity and the second cavity to form a light blocking layer surrounding the light emitting device.

Another feature of this invention provides a method of manufacturing a sensing chip package as mentioned above, wherein the sensor is a proximity sensor.

Another feature of this invention provides a method of manufacturing a sensing chip package as mentioned above, wherein the light blocking material layer is a black resistant which can absorb light.

Another feature of this invention provides a method of manufacturing a sensing chip package as mentioned above, wherein the light blocking material layer is a metal with a high reflection coefficient or a distributed Bragg reflector.

Another feature of this invention provides a method of manufacturing a sensing chip package as mentioned above, wherein the light emitting device is a LED.

Another feature of this invention provides a method of manufacturing a sensing chip package as mentioned above, wherein the LED is a surface mounted LED selected from mesa-type LED, vertical-type LED and flip-chip LED mounted on the first top surface of the sensor by surface mounting technology.

Another feature of this invention provides a method of manufacturing a sensing chip package as mentioned above, wherein the LED is a non-surface mounted LED buried in the wafer and adjacent to the first top surface.

Another feature of this invention provides a method of manufacturing a sensing chip package as mentioned above, wherein the LED is an IR LED.

Another feature of this invention provides a method of manufacturing a sensing chip package as mentioned above, wherein the light sensing device is an IR sensor.

Another feature of this invention provides a method of manufacturing a sensing chip package as mentioned above, further comprising a first solder wire connecting to the first conductive pad and a second solder wire connecting to the second conductive pad.

Another feature of this invention provides a method of manufacturing a sensing chip package as mentioned above, further comprising a step of scribing the sensing areas to generate a plurality of sensing chip packages.

Another feature of this invention provides a method of manufacturing a sensing chip package as mentioned above, further comprising the steps of: thinning the first bottom surface of the wafer; forming an insulating layer on the first bottom surface of the wafer, and the insulating having a first through hole exposing the first conductive pad and a second through hole exposing the second conductive pad; forming a re-distribution layer on the insulating layer to interconnect the first conductive pad and the second conductive pad via the first through hole and second through hole respectively; forming a passivation layer to overlay the re-distribution layer, the first through hole and the second through hole, and the passivation having a first opening and a second opening; and forming a first conductive structure in the first opening and a second conductive structure in the second opening to interconnect the re-distribution layer respectively.

Another feature of this invention provides a method of manufacturing a sensing chip package as mentioned above, wherein the first structure and the second structure comprise solder ball, solder bumps and conductive pillars.

Another feature of this invention provides a method of manufacturing a sensing chip package as mentioned above, further comprising a step of scribing the sensing areas to generate a plurality of sensing chip packages.

Another feature of this invention provides a method of manufacturing a sensing chip package as mentioned above, further comprising the steps of: thinning the first bottom surface of the wafer; forming a third cavity exposing the first conductive pad and a fourth cavity exposing the second conductive pad on the first bottom surface of the wafer; forming an insulating layer on the first bottom surface of the wafer and overlaying the third cavity and the fourth cavity; removing the insulating in the third and the fourth cavities and part of the first and the second conductive pads, part of the adhesive layer and part of the cap layer above the third and the fourth cavities by notching to respectively form a first notch exposing an edge of the first conductive pad and a second notch exposing an edge of the second conductive pad; forming a re-distribution layer on the insulating layer, the first notch and the second notch to interconnect the exposed edges of the first and the second conductive pads respectively; forming a passivation layer to overlay the re-distribution layer, the first notch and the second notch, and the passivation having a third opening and a fourth opening; and forming a third conductive structure in the third opening and a fourth conductive structure in the fourth opening to interconnect the re-distribution layer respectively.

Another feature of this invention provides a method of manufacturing a sensing chip package as mentioned above, wherein the third structure and the fourth structure comprise solder ball, solder bumps and conductive pillars.

Another feature of this invention provides a method of manufacturing a sensing chip package as mentioned above, further comprising a steps of scribing the sensing areas to generate a plurality of sensing chip packages.

### BRIEF DESCRIPTION OF THE DRAWINGS

FIG. 1A is a top view of a conventional proximity sensing chip package.

FIG. 1B is a cross-sectional view of a conventional proximity sensing chip package as illustrated in FIG. 1A.

FIGS. 2A˜2E are cross-sectional views of a method of manufacturing a proximity sensing chip package according to the exemplary embodiment 1 of this present invention.

FIG. 3 is a top view of a proximity sensing chip package as illustrated in FIG. 2E.

FIG. 4 is a cross-sectional view of a proximity sensing chip package according to the exemplary embodiment 2 of this present invention.

FIG. 5 is a cross-sectional view of a proximity sensing chip package according to the exemplary embodiment 3 of this present invention.

FIG. 6 is a cross-sectional view of a proximity sensing chip package according to the exemplary embodiment 4 of this present invention.

FIG. 7 is a cross-sectional view of a proximity sensing chip package according to the exemplary embodiment 5 of this present invention.

FIG. 8 is a cross-sectional view of a proximity sensing chip package according to the exemplary embodiment 6 of this present invention.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific exemplary embodiments discussed are merely illustrative of specific methods to make and use the embodiments, and do not limit the scope of the disclosure.

### Exemplary Embodiment 1

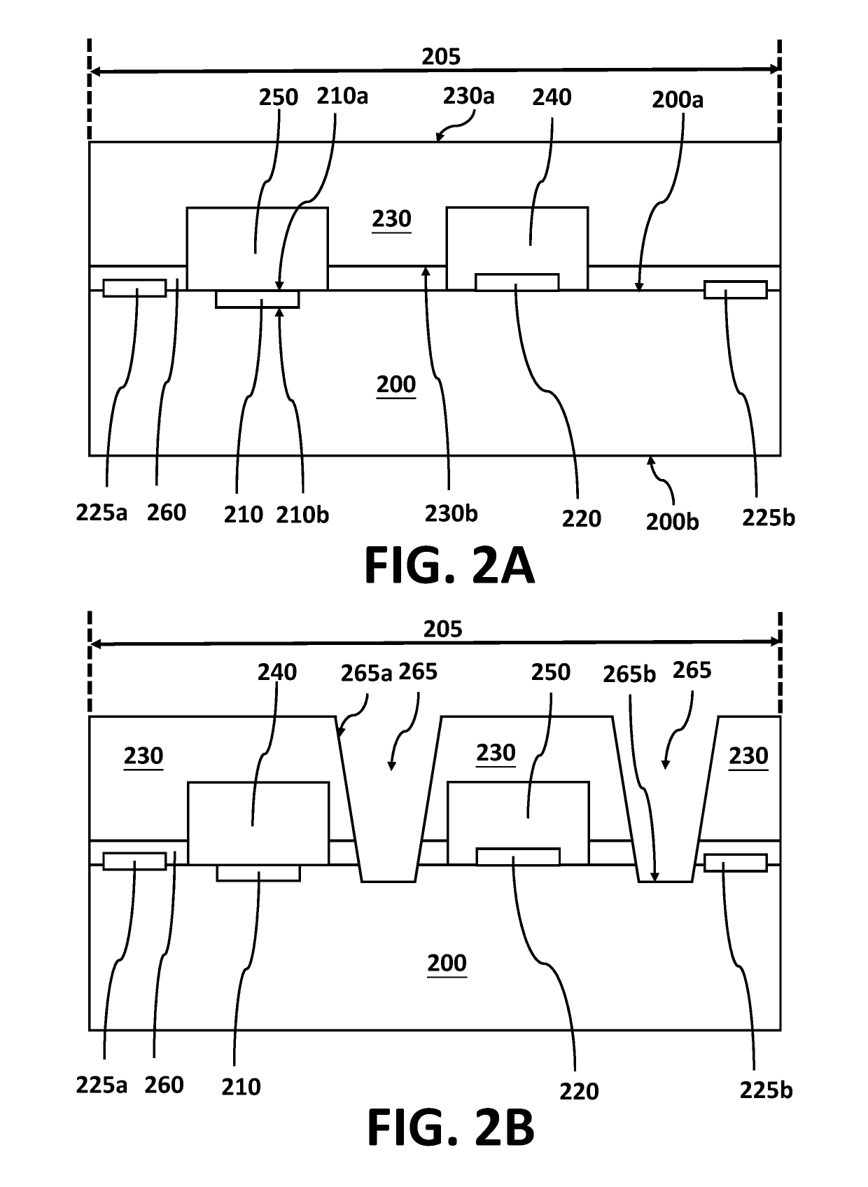

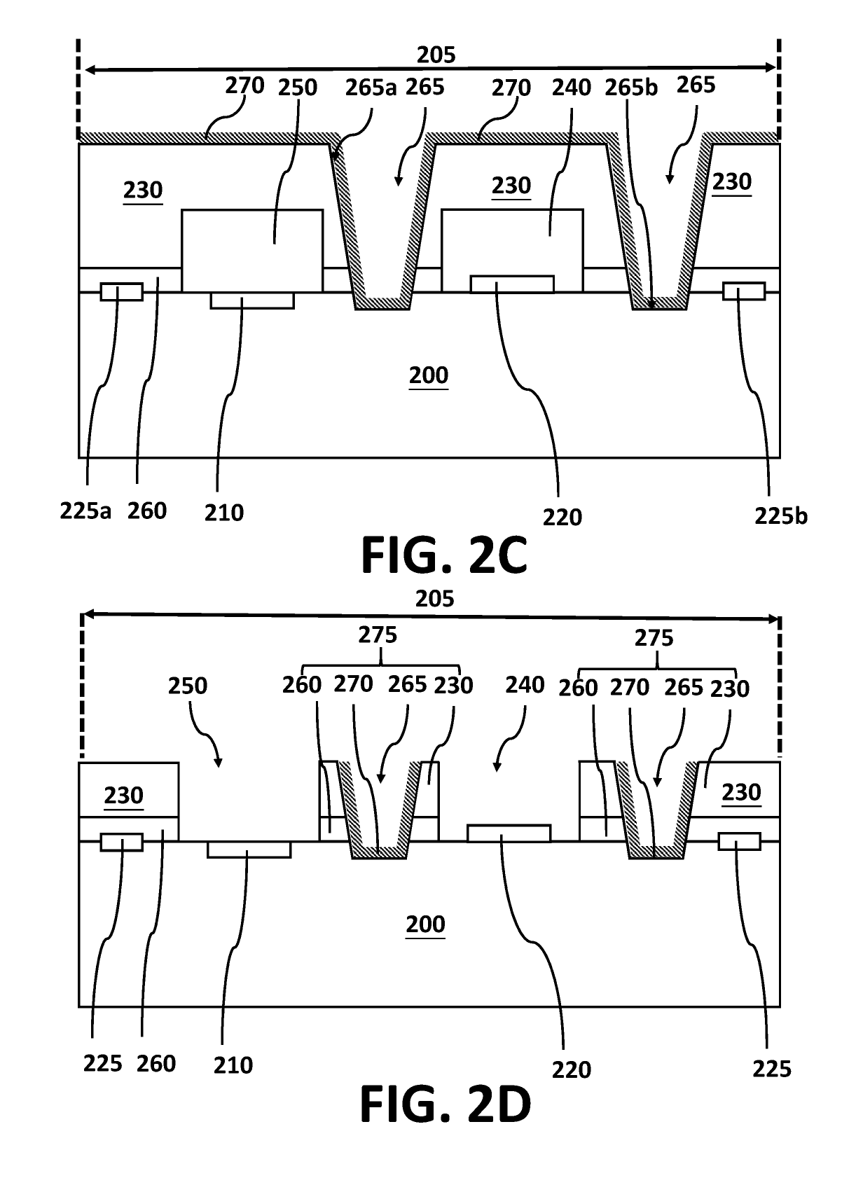

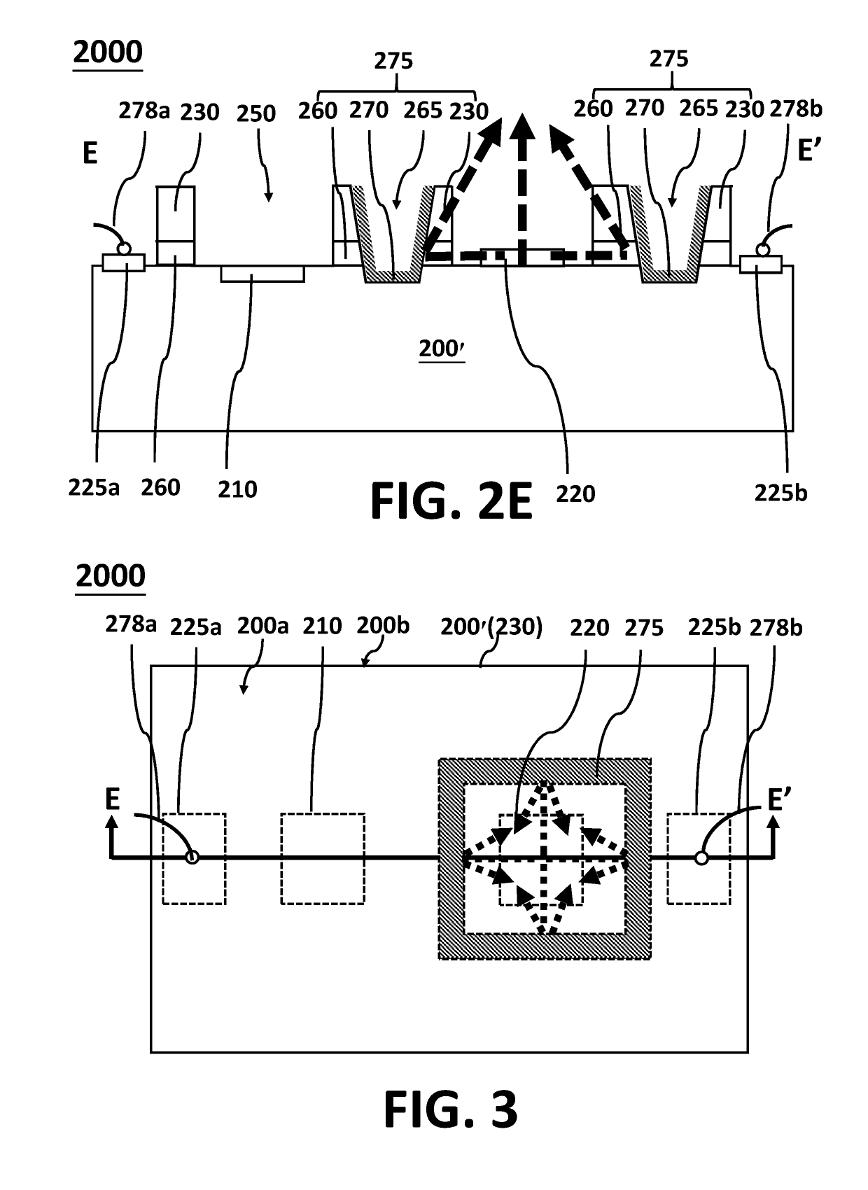

A detailed description of the proximity sensing chip package 2000 and a method of manufacturing the same according to embodiment 1 of this invention is given below with reference to the accompany FIGS. 2A˜2E.

First, please refer to FIG. 2A. A wafer 200 having a plurality of sensing areas 205 is provided, wherein each sensing area 205 having a first top surface 200a and a first bottom surface 200b opposite to each other comprises a light emitting device 220 and a light sensing device 210 having a second top surface 210a and a second bottom surface 210b opposite to each other depicted adjacent to the first top surface 200a and spaced with a pre-determined distance, and each sensing area 205 further comprises a first conductive pad 225a adjacent to the light emitting device 220 and a second conductive pad 225b adjacent to the light sensing device 210. Next, a cap layer having a third top surface 230a and a third bottom surface 230b opposite to each other is provided, wherein the third bottom surface 230b includes a first cavity 240 corresponding to the light emitting device 210b and a second cavity 250 corresponding to the light sensing device 210a. Then, the third bottom surface 230b of the cap layer 230 is bounded to the first top surface 200a by sandwiched an adhesive layer 260 therebetween.

The light emitting device 220 can be a light emitting diode (LED), such as a surface mounted LED including mesa-type LED, vertical-type LED or flip-chip LED mounted on the first top surface 200a of the sensing chip area 205, or a non-surface mounted LED buried in the wafer 200 adjacent to the first top surface 200a of the sensing chip area 205. The light emitting device 220 of this embodiment is an IR LED, and the light sensing device 210 of this embodiment is an IR sensor.

Next, please refers to FIG. 2B. A trench 265 surrounding the light emitting device 220 is formed on the third top surface 230a of the cap layer 230 by the photolithography and etching. The trench 265 passes through the cap layer 230, the adhesive layer and part of the first top surface 200a of the wafer 200, and the trench 265 has an inner wall 265a and a bottom 265b not higher than the second bottom surface 210b of the light sensing device 210.

Next, please refers to FIG. 2C, a light blocking material layer 270 is formed to overlay the third top surface 230a, and the inner wall 265a and the bottom wall 265b of the trench 265. The light blocking material layer 270 of other embodiments according to this invention can also be gap-filled into the trench 265. The light blocking material layer 270 is a black resistant which can absorb light, or a metal with a high reflection coefficient such as silver or aluminum or a distributed Bragg reflector.

Next, please refer to FIG. 2D, the third top surface 230a of the cap layer 230 and the light blocking material layer 270 above the first cavity 240 and the second cavity 250 is removed by polishing to make the first cavity 240 and the second cavity 250 pass through the cap layer 230 and form a light blocking layer 275 surrounding the light emitting device 220.

Next, please refer to FIG. 2E, part of the adhesive layer 260 and cap layer 230 above the first conductive pad 225a and the second conductive pad 225b is removed to expose the first conductive pad 225a and the second conductive pad 225b. Then, each sensing area 205 of the wafer is scribed to form a plurality of sensors 200′. Finally, a first solder wire 278a and a second solder wire 278b are wired bounded to the first conductive pad 225a and the second conductive pad 225b of each sensor 200′ respectively to form a proximity sensing chip package 2000.

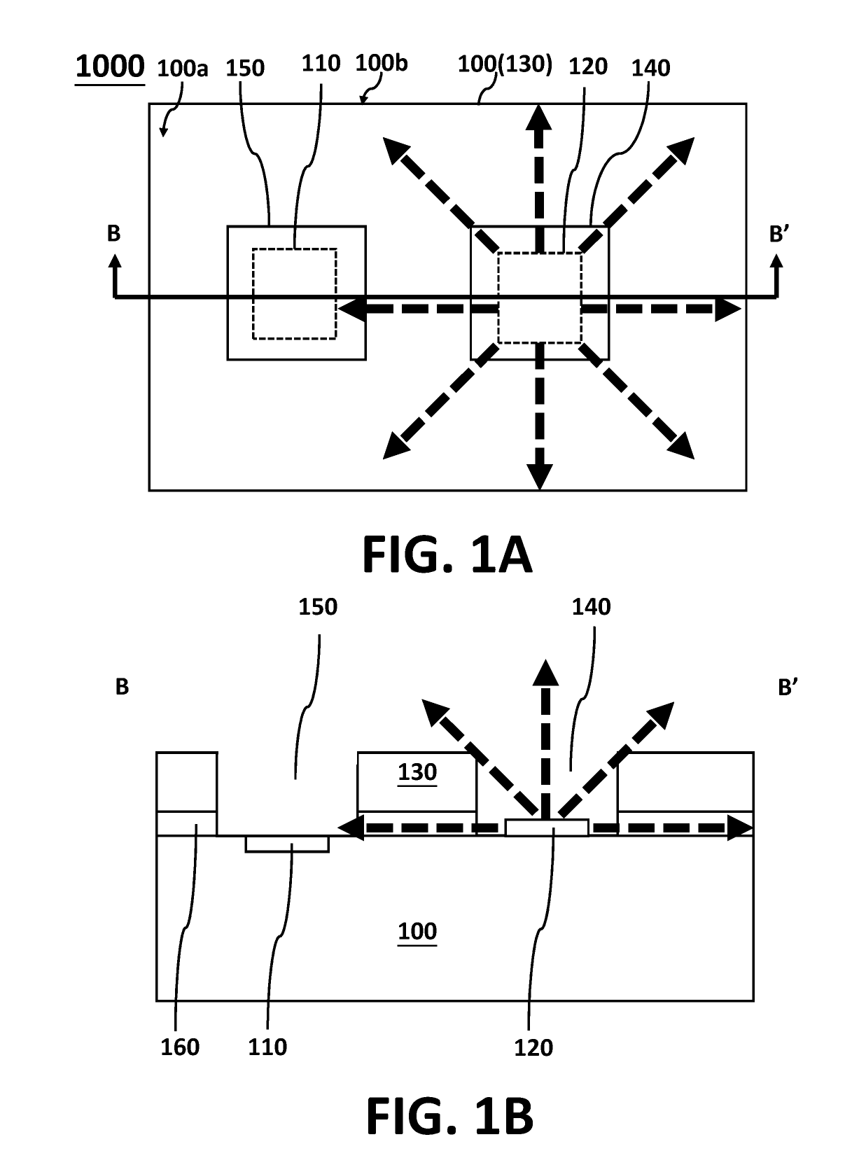

As the top view of the proximity sensing chip package 2000 illustrated in FIG. 3, the light emitting device 220 is surrounded by the blocking layer 275, so the lateral light emitted by the light emitting device 220 will not reach the sensing device 210. The light sensing device 210 will not be interfered by the later light emitted by the light emitting device 220. Accordingly, the proximity sensing chip package 2000 according to the embodiment 1 of this invention is more sensitive than the conventional proximity sensing device 1000 illustrated in FIGS. 1A˜1B.

### Exemplary Embodiment 2

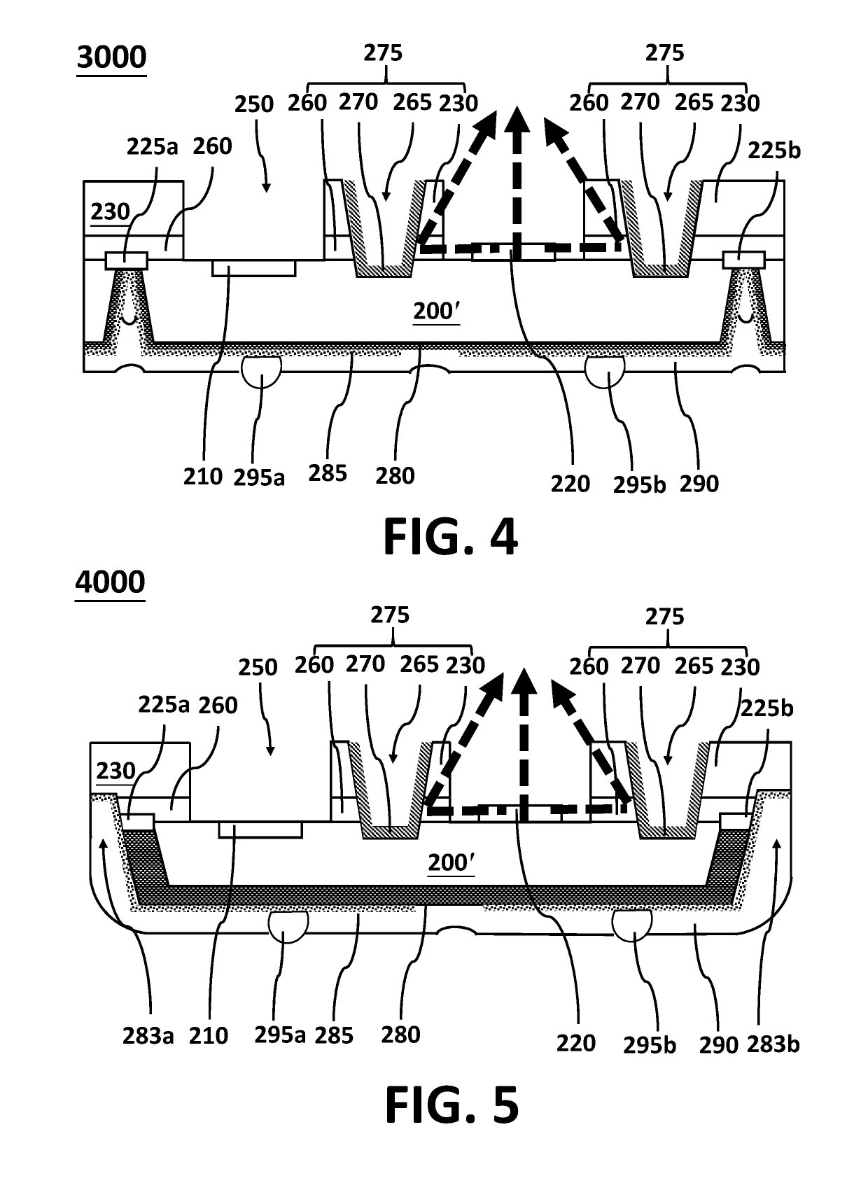

A detailed description of the proximity sensing chip package 3000 and a method of manufacturing the same according to embodiment 2 of this invention is given below with reference to the accompany FIG. 4.

The feature of this embodiment 2 is to treat the first bottom surface 200b of the wafer 200 of the structure as illustrated in FIG. 2D of the embodiment 1 by a so-called through silicon via process. The first bottom surface 200b of the wafer 200 is thinned first, then an insulating layer 280 is formed on the first bottom surface 200b of the wafer 200. The insulating layer 280 has a first through hole (not shown) exposing the first conductive pad 225a and a second through hole (not shown) exposing the second conductive pad 225b. Next, a re-distribution layer 285 is formed on the insulating layer 280 to interconnect the first conductive pad 225a and the second conductive pad 225b via the first through hole (not shown) and second through hole (not shown) respectively. Next, a passivation layer 290 having a first opening (not shown) and a second opening (not shown) is formed to overlay the re-distribution layer 285 and the first through hole (not shown) and the second through hole (not shown), then a first conductive structure 295a and a second conductive structure 295b are formed in the first opening (not shown) and the second opening (not shown) to interconnect the re-distribution layer 285 respectively.

Finally, each sensing area 205 of the wafer 200 is scribed to form a plurality of sensing chip package 3000 as illustrated in FIG. 4, wherein each sensing chip package 3000 has a sensor 200′ with TSV structures on its first bottom surface 200a comprising a light emitting device 220, a light sensing device 210, a first conductive pad 225a, a second conductive pad 225b and a light blocking layer 275 surrounding the light emitting device 220.

Similarly, the light sensing device 210 will not be interfered by the later light emitted by the light emitting device 220. Accordingly, the proximity sensing chip package 3000 according to the embodiment 2 of this invention is more sensitive than the conventional proximity sensing device 1000 illustrated in FIGS. 1A˜1B.

### Exemplary Embodiment 3

A detailed description of the proximity sensing chip package 4000 and a method of manufacturing the same according to embodiment 3 of this invention is given below with reference to the accompany FIG. 5.

The feature of this embodiment 3 is to treat the first bottom surface 200b of the wafer 200 of the structure as illustrated in FIG. 2D of the embodiment 1 by a so-called T-contact process. The first bottom surface 200b of the wafer 200 is thinned to form a third cavity (not shown) and a fourth cavity (not shown) passing the first bottom surface 200b and exposing the first conductive pad 225a and the second conductive pad 225b respectively. Next, an insulating layer 280 is formed on the first bottom surface 200b of the wafer 200. The insulating layer 280 is formed on the first bottom surface 200b of the wafer 200 and overlaid the third cavity (not shown) and the fourth cavity (not shown). Next, the insulating layer 280 in the third and the fourth cavities (not shown) and part of the first and the second conductive pads 225a, 225b, part of the adhesive layer 260 and part of the cap layer 230 above the third and the fourth cavities (not shown) are removed by notching to respectively form a first notch 283a exposing an edge of the first conductive pad 225a and a second notch 283b exposing an edge of the second conductive pad 225b. Next, a re-distribution layer 285 is formed on the insulating layer 280 and overlaid the side-walls of the first notch 283a and the second notch 283b to interconnect the exposed edges of the first and the second conductive pads 225a, 225b respectively. Next, a passivation layer 290 having a third opening (not shown) and a fourth opening (not shown) is formed to overlay the re-distribution layer 285 and the first notch 283a and the second notch 283b. Next, a third conductive structure 295a is formed in the third opening (not shown) and a fourth conductive structure 295b in the fourth opening (not shown) to interconnect the re-distribution layer 285 respectively.

Finally, each sensing area 205 of the wafer 200 is scribed to form a plurality of sensing chip package 4000 as illustrated in FIG. 5, wherein each sensing chip package 4000 has a sensor 200′ with T-contact structures on its first bottom surface 200a comprising a light emitting device 220, a light sensing device 210, a first conductive pad 225a, a second conductive pad 225b and a light blocking layer surrounding the light emitting device 220.

Similarly, the light sensing device 210 will not be interfered by the later light emitted by the light emitting device 220. Accordingly, the proximity sensing chip package 3000 according to the embodiment 2 of this invention is more sensitive than the conventional proximity sensing device 1000 illustrated in FIGS. 1A˜1B.

### Exemplary Embodiment 4

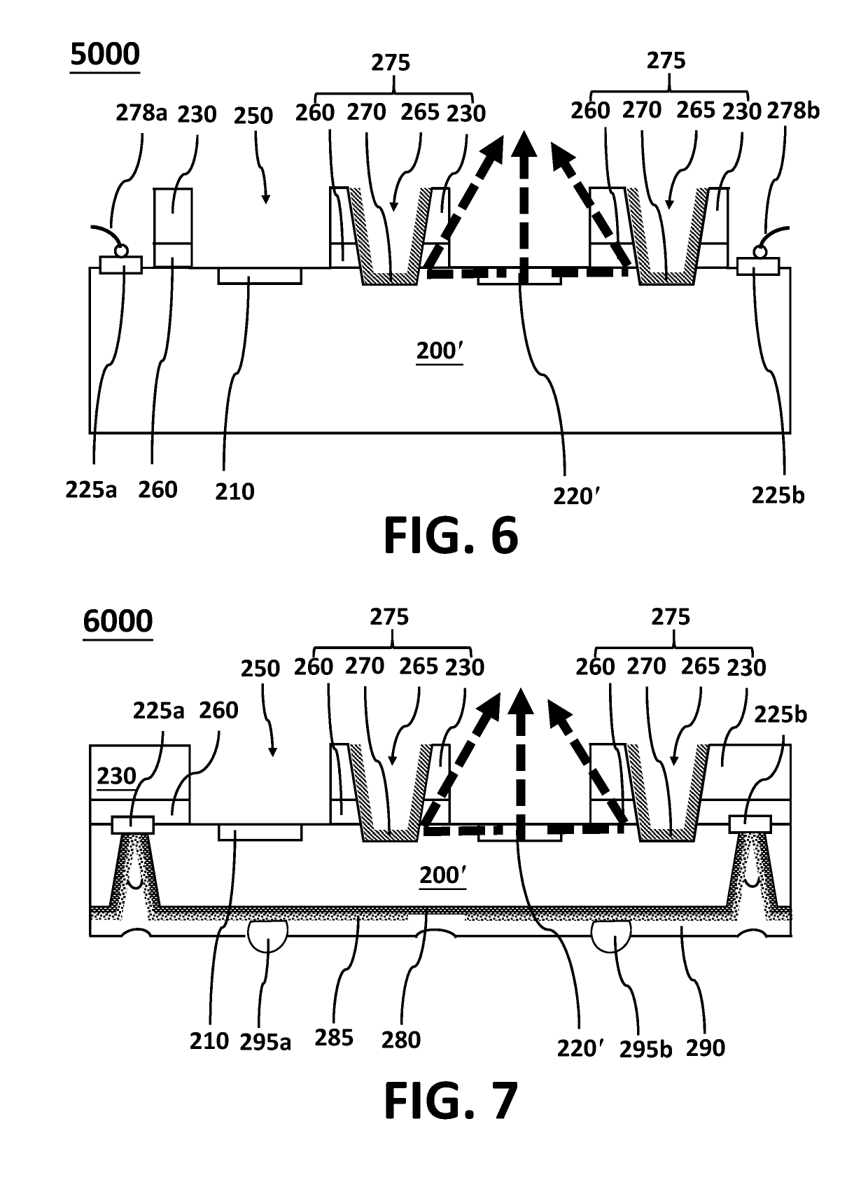

A detailed description of the proximity sensing chip package 5000 and a method of manufacturing the same according to embodiment 4 of this invention is given below with reference to the accompany FIG. 6.

As illustrated in FIG. 6, the proximity sensing chip package 5000 of the embodiment 4 according to this invention is manufactured by similar processes as that described in embodiment 1. The only one difference is that the light emitting device 220′ of the sensing device 200′ is replaced with a non-surface mounted LED which can be directly formed within the sensor 200′ by LED processes or finished by burying a LED chip in the sensing device 200′.

Similarly, the light sensing device 210 will not be interfered by the later light emitted by the light emitting device 220. Accordingly, the proximity sensing chip package 5000 according to the embodiment 4 of this invention is more sensitive than the conventional proximity sensing device 1000 illustrated in FIGS. 1A˜1B.

### Exemplary Embodiment 5

A detailed description of the proximity sensing chip package 6000 and a method of manufacturing the same according to embodiment 5 of this invention is given below with reference to the accompany FIG. 7.

As illustrated in FIG. 7, the proximity sensing chip package 6000 of the embodiment 5 according to this invention is manufactured by similar processes as that described in embodiment 2. The only one difference is that the light emitting device 220′ of the sensor 200′ is replaced with a non-surface mounted LED which can be directly formed within the sensing device 200′ by LED processes or finished by burying a LED chip in the sensing device 200′.

Similarly, the light sensing device 210 will not be interfered by the later light emitted by the light emitting device 220. Accordingly, the proximity sensing chip package 6000 according to the embodiment 5 of this invention is more sensitive than the conventional proximity sensing device 1000 illustrated in FIGS. 1A˜1B.

### Exemplary Embodiment 6

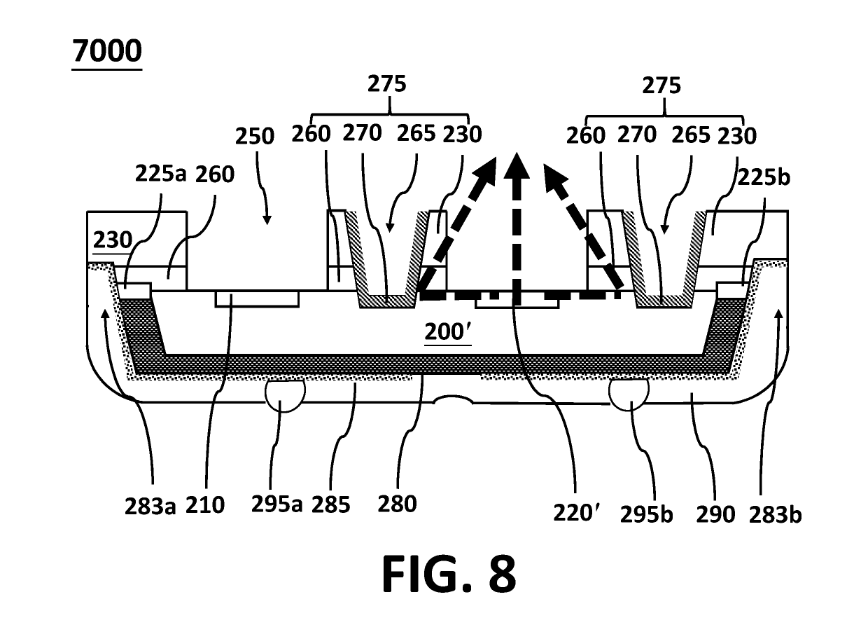

A detailed description of the proximity sensing chip package 6000 and a method of manufacturing the same according to embodiment 6 of this invention is given below with reference to the accompany FIG. 8.

As illustrated in FIG. 8, the proximity sensing chip package 6000 of the embodiment 6 according to this invention is manufactured by similar processes as that described in embodiment 3. The only one difference is that the light emitting device 220′ of the sensor 200′ is replaced with a non-surface mounted LED which can be directly formed within the sensing device 200′ by LED processes or finished by burying a LED chip in the sensing device 200′.

Similarly, the light sensing device 210 will not be interfered by the later light emitted by the light emitting device 220. Accordingly, the proximity sensing chip package 5000 according to the embodiment 4 of this invention is more sensitive than the conventional proximity sensing device 1000 illustrated in FIGS. 1A˜1B.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A sensing chip package, comprising:
a sensor, having a first top surface and a first bottom surface opposite to each other, comprising a light emitting device and a light sensing device are depicted adjacent to the first top surface and spaced with a pre-determined distance, and a first conductive pad adjacent to the light emitting device and a second conductive pad adjacent to the light sensing device, whereby the light sensing device having a second top surface and a second bottom opposite to each other; and
a light blocking layer formed on the first top surface of the sensor and surrounded the light emitting device, comprising:
a cap layer having a third top surface and a third bottom surface opposite to each other formed on the first top surface of the sensor, and the cap layer having a trench with an inner wall and a bottom wall not higher than the second bottom surface of the light sensing device;
an adhesive layer sandwiched between the cap layer and the first top surface of the sensor to bound the cap layer to the first top surface of the sensor; and
a light blocking material layer overlaid the inner wall of the trench or gap-filled in the trench.

2. The sensing chip package as claimed in claim 1, wherein the sensor is a proximity sensor.

3. The sensing chip package as claimed in claim 1, wherein the light blocking material layer is a black resistant which can absorb light or a metal with a high reflection coefficient or a distributed Bragg reflector.

4. The sensing chip package as claimed in claim 1, wherein the LED is a surface mounted LED selected from mesa-type LED, vertical-type LED and flip-chip LED mounted on the first top surface of the sensor by surface mounting technology, or a non-surface mounted LED buried in the wafer and adjacent to the first top surface.

5. The sensing chip package as claimed in claim 4, wherein the LED is an IR LED.

6. The sensing chip package as claimed in claim 5, wherein the light sensing device is an IR sensor.

7. The sensing chip package as claimed in claim 1, further comprising a first solder wire connecting to the first conductive pad and a second solder wire connecting to the second conductive pad.

8. The sensing chip package as claimed in claim 1, further comprising:
an insulating layer, formed on the first bottom surface of the sensor, having a first through hole exposing the first conductive pad and a second through hole exposing the second conductive pad;
a re-distribution layer formed on the insulating layer and interconnected the first conductive pad and the second conductive pad via the first through hole and the second through hole respectively;
a passivation layer overlaid the re-distribution layer, the first through hole, the second through hole, wherein the passivation layer has a first opening and a second opening exposing the re-distribution layer; and
a first conductive structure formed in the first opening and a second conductive structure formed in the second opening and respectively interconnected to the re-distribution layer.

9. The sensing chip package as claimed in claim 1, further comprising:
an insulating layer, formed on the first bottom surface of the sensor, having a first notch exposing an edge of the first conductive pad and a second notch exposing an edge of the second conductive pad, and part of the third bottom surface of the cap layer;
a re-distribution layer formed on the insulating layer, the first notch and the second notch to interconnect the exposed edges of the first and the second conductive pads respectively;
a passivation layer overlaid the re-distribution layer, the first notch and the second notch, wherein the passivation layer has a third opening and a fourth opening exposing the re-distribution layer; and
a third conductive structure formed in the third opening and a fourth conductive structure formed in the fourth opening and respectively interconnected to the re-distribution layer.

10. A method of manufacturing a sensing chip package, comprising the steps of:
providing a wafer having a plurality of sensing areas, each sensing area comprising a sensor having a first top surface and a first bottom surface opposite to each other comprising a light emitting device and a light sensing device are depicted adjacent to the first top surface and spaced with a pre-determined distance, and a first conductive pad adjacent to the light emitting device and a second conductive pad adjacent to the light sensing device, whereby the light sensing device having a second top surface and a second bottom opposite to each other;
providing a cap layer having a third top surface and a third bottom surface opposite to each other, and the third bottom surface corresponding to each of the sensing areas including a first cavity corresponding to the light emitting device and a second cavity corresponding to the light sensing device;
bonding the third bottom surface of the cap layer to the first top surface of the wafer by sandwiched an adhesive layer therebetween;
forming a trench passing through the cap layer, the adhesive layer and part of the first top surface of the wafer and surrounding the light emitting device, wherein the trench has an inner wall and a bottom wall not higher than the light sensing device;
formed on the first top surface of the sensor, and the cap layer having a trench with an inner wall and a bottom wall not higher than the second bottom surface of the light sensing device;
forming a light blocking material layer to overlay the inner wall of the trench or gap-fill into the trench; and
removing the third top surface of the cap layer and the light blocking layer above the first cavity and the second cavity to form a light blocking layer surrounding the light emitting device.

11. The method of manufacturing a sensing chip package as claimed in claim 10, wherein the sensor is a proximity sensor.

12. The method of manufacturing a sensing chip package as claimed in claim 10, wherein the light blocking material layer is a black resistant which can absorb light or a metal with a high reflection coefficient or a distributed Bragg reflector.

13. The method of manufacturing a sensing chip package as claimed in claim 10, wherein the LED is a surface mounted LED selected from mesa-type LED, vertical-type LED and flip-chip LED mounted on the first top surface of the sensor by surface mounting technology or a non-surface mounted LED buried in the wafer and adjacent to the first top surface.

14. The method of manufacturing a sensing chip package as claimed in claim 13, wherein the LED is an IR LED.

15. The method of manufacturing a sensing chip package as claimed in claim 14, the light sensing device is an IR sensor.

16. The method of manufacturing a sensing chip package as claimed in claim 10, further comprising a first solder wire connecting to the first conductive pad and a second solder wire connecting to the second conductive pad.

17. The method of manufacturing a sensing chip package as claimed in claim 10, further comprising a step of scribing the sensing areas to generate a plurality of sensing chip packages.

18. The method of manufacturing a sensing chip package as claimed in claim 10, further comprising the steps of:
thinning the first bottom surface of the wafer;
forming an insulating layer on the first bottom surface of the wafer, and the insulating having a first through hole exposing the first conductive pad and a second through hole exposing the second conductive pad;
forming a re-distribution layer on the insulating layer to interconnect the first conductive pad and the second conductive pad via the first through hole and second through hole respectively;
forming a passivation layer to overlay the re-distribution layer, the first through hole and the second through hole, and the passivation having a first opening and a second opening; and
forming a first conductive structure in the first opening and a second conductive structure in the second opening to interconnect the re-distribution layer respectively.

19. The method of manufacturing a sensing chip package as claimed in claim 18, further comprising a step of scribing the sensing areas to generate a plurality of sensing chip packages.

20. The method of manufacturing a sensing chip package as claimed in claim 10, further comprising the steps of:
thinning the first bottom surface of the wafer;
forming a third cavity exposing the first conductive pad and a fourth cavity exposing the second conductive pad on the first bottom surface of the wafer;
forming an insulating layer on the first bottom surface of the wafer and overlaying the third cavity and the fourth cavity;
removing the insulating in the third and the fourth cavities and part of the first and the second conductive pads, part of the adhesive layer and part of the cap layer above the third and the fourth cavities by notching to respectively form a first notch exposing an edge of the first conductive pad and a second notch exposing an edge of the second conductive pad;
forming a re-distribution layer on the insulating layer, the first notch and the second notch to interconnect the exposed edges of the first and the second conductive pads respectively;
forming a passivation layer to overlay the re-distribution layer, the first notch and the second notch, and the passivation having a third opening and a fourth opening; and
forming a third conductive structure in the third opening and a fourth conductive structure in the fourth opening to interconnect the re-distribution layer respectively.

21. The method of manufacturing a sensing chip package as claimed in claim 20, further comprising a step of scribing the sensing areas to generate a plurality of sensing chip packages.
